(19) United States
(12) Patent Application Publication
(10) Pub. No.: US 2026/0367138 A1
(43) Pub. Date: Nov. 19, 2026

(54) DEVICE-TESTING CIRCUIT STRUCTURE AND SYSTEM APPLYING THE SAME

(71) Applicant: UNITED MICROELECTRONICS CORP., Hsinchu (TW)

(72) Inventors: Chien-Yi Lee, Hsinchu City (TW); Tse-Pu CHEN, New Taipei City (TW); Yi-Chin Li, Hualien County (TW); Sheng-Huei DAI, Taitung County (TW)

(21) Appl. No.: 19/250,421

(22) Filed: Jun. 26, 2025

(30) Foreign Application Priority Data
May 16, 2025 (TW) 114118425

(51) Int. Cl. G01R 31/28

(52) U.S. Cl. CPC G01R 31/2822; G01R 31/2879

(57) ABSTRACT

A device-testing circuit structure used for testing a device under test disposed on a semiconductor substrate includes a first RF pad used to receive at least one RF input signal and transit it to the device under test; a second RF pad electrically connected to the device under test and used to output at least one first test signal from the device under test; a first DC pad used to receive at least one DC input signal and transit it to the device under test; a second DC pad used to output at least one second test signal from the device under test; and a first DC blocking device with one end connected to the first DC pad or the second DC pad and another end correspondingly connected to the first RF pad or the second RF pad.

This application claims the benefit of Taiwan Application Serial No. 114118425 filed at May 16, 2025 the subject matter of which is incorporated herein by reference.

### BACKGROUND

### Technical Field

The disclosure relates to a semiconductor device-testing circuit structure and the system applying the same, and more particularly to a circuit structure and system for detecting signals from a semiconductor device and determine its reliability based on the signal characteristics.

### Description of Background

Typically, the reliability of integrated circuit (IC) devices (e.g., field-effect transistors (FETs), resistors, capacitors, etc.) can be estimated by measuring the direct current (DC) signal characteristics of the integrated circuit devices, and the service life of the IC devices can be further accurately predicted.

However, when the IC devices are further used in radio frequency (RF) operations, the RF swing voltage may exceed the maximum allowed DC bias tolerance of the DC testing circuit structure, thereby triggering the failure mechanism of the testing circuit structure (for example, hot carrier degradation, time-dependent dielectric breakdown, etc.), and resulting in unstable test signals and inaccurate prediction.

It is necessary to individually test and analyze the RF signals of the IC devices in order to accurately predict their service life under RF applications. For the purpose of operation convenience, several testing systems and methods that use the same testing circuit structure to measure the DC signal and RF signal characteristics of the IC devices respectively have been provided, so as to perform reliability testing and service life analysis on the IC devices at different operations.

The conventional testing circuit structure requires an additional T-type bias tee with capacitors/inductors, serving as a low-pass filter, set on the input/output probe of the testing circuit structure. When testing and analyzing DC and RF signals, the DC and RF signals can be separated and then transmitted to the device under test (DUT) through a plurality of pads. However, this design not only increases additional cost for manufacturing the testing circuit structure, but also increases the size of the testing circuit structure, due to the fact that it is not easy to integrate the T-type bias tee with additional volume into the testing circuit structure.

Furthermore, since the reference plane for measuring the DC signal needs to pass through the T-type bias tee before being electrically contacted with the DUT, thus it may cause a voltage drop in the DC signal and result in signal instability.

Therefore, there is a need of providing a device-testing circuit structure and the system applying the same to obviate the drawbacks encountered from the prior art.

### SUMMARY

One aspect of the present disclosure is to provide a device-testing circuit structure used to test a DUT disposed on a semiconductor substrate, wherein the device-testing circuit structure includes a first RF pad, a second RF pad, a first DC pad, a second DC pad and a first DC blocking element. The first RF pad is disposed on the semiconductor substrate, and is used to receive at least one RF input signal and transit it to the DUT. The second RF pad is disposed on the semiconductor substrate, electrically connected to the DUT, and is used to output at least one first test signal from the DUT. The first DC pad is disposed on the semiconductor substrate and is used to receive at least one DC input signal and transit it to the DUT. The second DC pad is disposed on the semiconductor substrate and is used to output at least one second test signal from the DUT. The first DC blocking element is disposed on the semiconductor substrate, and one end of the first DC blocking element is connected to the first DC pad or the second DC pad; another end of the first DC blocking element is correspondingly connected to the first RF pad or the second RF pad.

Another aspect of the present disclosure is to provide a device-testing system used to test a DUT disposed on a semiconductor substrate, wherein the device-testing system includes a first RF pad, a second RF pad, a first DC pad, a second DC pad, a first DC blocking element, a first probe, a second probe, a third probe, and a fourth probe. The first RF pad is disposed on the semiconductor substrate, and is used to receive at least one RF input signal and transit it to the DUT. The second RF pad is disposed on the semiconductor substrate, electrically connected to the DUT, and is used to output at least one first test signal from the DUT. The first DC pad is disposed on the semiconductor substrate and is used to receive at least one DC input signal and transit it to the DUT. The second DC pad is disposed on the semiconductor substrate and is used to output at least one second test signal from the DUT. The first DC blocking element is disposed on the semiconductor substrate, and one end of the first DC blocking element is connected to the first DC pad or the second DC pad; another end of the first DC blocking element is correspondingly connected to the first RF pad or the second RF pad. The first probe is used to contact the first RF pad and output the at least one RF input signal. The second probe contacts the second RF pad and is used to form an RF signal testing loop with the DUT, the first RF pad and the first probe to output the at least one first test signal. The third probe contacts the first DC pad and is used to output the at least one DC input signal. The fourth probe contact the second DC pad and is used to form a DC signal testing loop with the DUT, the first DC pad and the third probe to output the at least one second test signal.

In accordance with the aforementioned embodiments of the present disclosure, a device-testing circuit structure and a device-testing system applying the same are provided, which includes a RF testing circuit disposed on a semiconductor substrate (e.g., a semiconductor wafer or a semiconductor chip/die) for testing a DUT. The RF testing circuit includes a first RF pad for receiving an RF input signal and transmit it into the DUT, and a second RF pad for outputting a test signal from the DUT. At least one DC pad is added to the connection line between the first RF pad and the DUT or/and between the second RF pad and the DUT, so that one end of the DC pad is directly electrically connected to the DUT, forming a DC testing loop with the DUT. Thereby, the reference layer of the DC testing loop can be directly connected to the DUT without passing through the first RF pad or the second RF pad, which helps to improve the problem of signal instability caused by voltage drop of the DC signal.

In addition, at least one DC blocking element (e.g., metal-oxide-metal (MOM)) capacitor, metal-insulator-metal (MIM) capacitor or resistor) is added between the first DC pad and the corresponding first RF pad and/or between the second DC pad and the corresponding second RF pad to block the interference of the DC signal coming from the DC pad bothering the RF test circuit. As a result, the device-testing circuit structure and device-testing system can detect the RF and DC signal characteristics of the DUT respectively, without additionally setting bias tee on the probe, as the prior art does. These designs can not only improve the stability of the DC signal, but also further simplify the structures of the device-testing circuit structure and the device-testing system.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIG. 1A is a top view illustrating a device-testing circuit structure according to one embodiment of the present disclosure;

FIG. 1B is a cross-sectional view of the device-testing circuit structure taken along the cutting-line C11 as depicted in FIG. 1A;

FIG. 1C is a cross-sectional view of the device-testing circuit structure taken along the cutting-line C12 as depicted in FIG. 1A;

FIG. 1D is a schematic diagram illustrating a device-testing system applying the device-testing circuit structure described in FIGS. 1A-1C;

FIG. 2A is a top view illustrating another device-testing circuit structure according to another embodiment of the present disclosure;

FIG. 2B is a cross-sectional view of the device-testing circuit structure taken along the cutting-line C21 as depicted in FIG. 2A;

FIG. 2C is a cross-sectional view of the device-testing circuit structure taken along the cutting-line C22 as depicted in FIG. 2A;

FIG. 2D is a schematic diagram illustrating another device-testing system applying the device-testing circuit structure described in FIGS. 2A-2C;

FIG. 3A is a top view illustrating yet another device-testing circuit structure according to another embodiment of the present disclosure;

FIG. 3B is a cross-sectional view of the device-testing circuit structure taken along the cutting-line C31 as depicted in FIG. 3A;

FIG. 3C is a cross-sectional view of the device-testing circuit structure taken along the cutting-line C32 as depicted in FIG. 3A; and

FIG. 3D is a schematic diagram illustrating yet another device-testing system applying the device-testing circuit structure described in FIGS. 3A-3C.

### DETAILED DESCRIPTION

The embodiments as disclosed below provide a device-testing circuit structure and the system applying the same, which can improve the stability of DC signals by using the same testing circuit structure to detect and analysis the DC signal and RF signal characteristics of IC devices, as well can further simplify the structure of the device-testing circuit system. The present disclosure will now be described more specifically with reference to the following embodiments illustrating the structure, method and arrangements thereof.

It is to be noted that the following descriptions of preferred embodiments of this disclosure are presented herein for purpose of illustration and description only. It is not intended to be exhaustive or to be limited to the precise form disclosed. Also, it is important to point out that there may be other features, elements, steps, and parameters for implementing the embodiments of the present disclosure which are not specifically illustrated. Thus, the descriptions and the drawings are to be regard as an illustrative sense rather than a restrictive sense. Various modifications and similar arrangements may be provided by the persons skilled in the art within the spirit and scope of the present disclosure. In addition, the illustrations may not be necessarily drawn to scale, and the identical elements of the embodiments are designated with the same reference numerals.

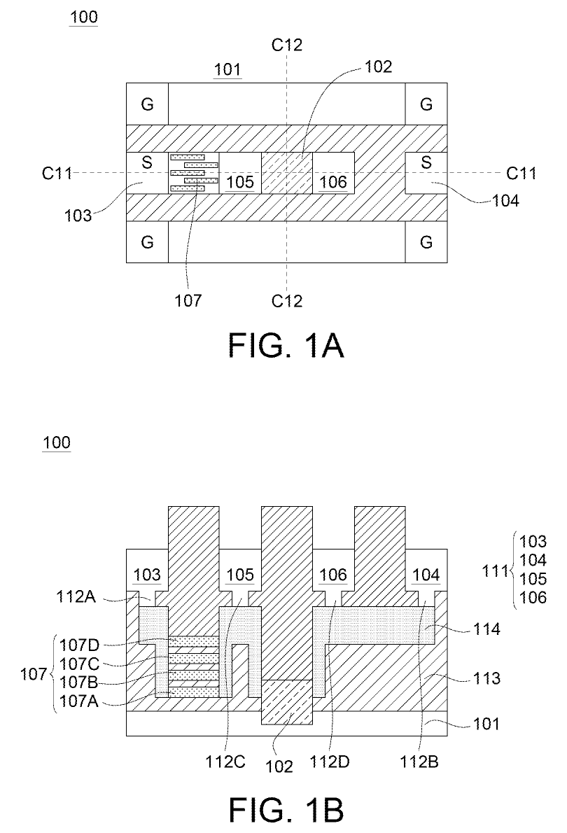

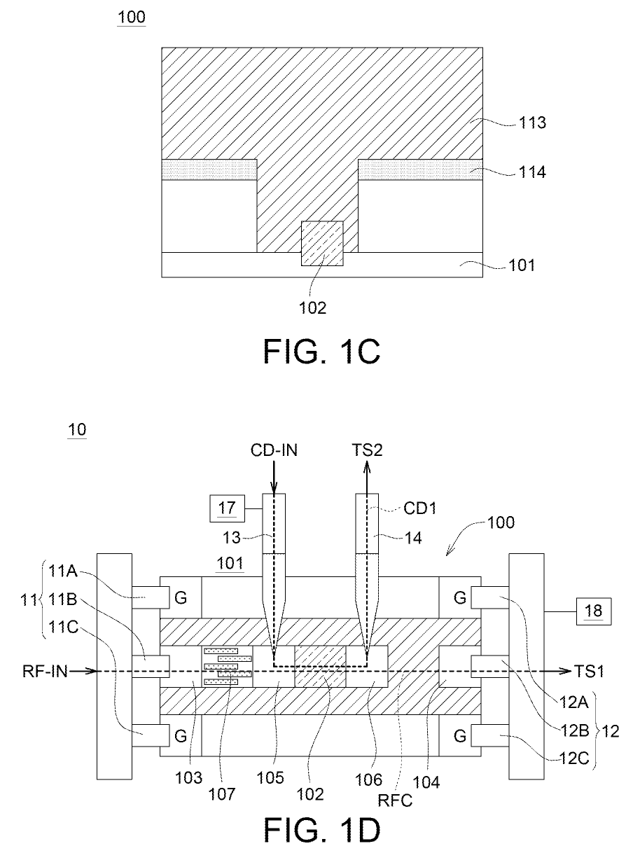

Referring to FIGS. 1A-1D, FIG. 1A is a top view illustrating a device-testing circuit structure 100 according to one embodiment of the present disclosure; FIG. 1B is a cross-sectional view of the device-testing circuit structure 100 taken along the cutting-line C11 as depicted in FIG. 1A; FIG. 1C is a cross-sectional view of the device-testing circuit structure 100 taken along the cutting-line C12 as depicted in FIGS. 1A; and 1D is a schematic diagram illustrating a device-testing system 10 applying the device-testing circuit structure 100 described in FIGS. 1A-C.

The device-testing system 10 is electrically connected to the device-testing circuit structure 100 disposed on a semiconductor substrate 101 through RF probes 11 and 12 and DC probes 13 and 14; and is used to detect DC signals and RF signals of a DUT 102 disposed on the semiconductor substrate 101, and further used to perform a characteristic analysis on the detected DC signals and RF signals, so as to determine the functional state of the DUT 102, and further to estimate the service life of the DUT 102.

For example, in some embodiments of the present disclosure, the semiconductor substrate 101 may be a semiconductor wafer, a semiconductor chip or a semiconductor die. The DUT 102 may be a field effect transistor (FET), a resistor or a capacitor. In the present embodiment, the device-testing circuit structure 100 is a circuit structure disposed on a semiconductor wafer (the semiconductor substrate 101) for respectively testing and analyzing the DC signal and RF signal characteristics of a FET (the DUT 102) disposed on the semiconductor wafer. The device-testing circuit structure 100 includes a first RF pad 103, a second RF pad 104, a first DC pad 105, a second DC pad 106 and a DC blocking element 107.

The first RF pad 103 may be a metal landing area in a patterned metal layer 111 disposed on the semiconductor substrate (semiconductor wafer) 101. The first RF pad 103 can be electrically contacted with the wire redistribution layer 114 disposed on the semiconductor substrate 101 through a metal contact via 112A passing through an interlayer dielectric layer (ILD) 113 disposed above the semiconductor substrate (the semiconductor wafer) 101, and can be electrically connected to the DUT (the FET) 102 through the wire redistribution layer 114. The first RF pad 103 is used to receive at least one RF input signal RF-IN input from the detection controller (not shown) of the device-testing system 10 through the RF probe 11, and transmit the at least one RF input signal RF-IN to the DUT (the FET) 102.

The second RF pad 104 is another metal landing area disposed in the patterned metal layer 111. The second RF pad 104 can be electrically connected to the wire redistribution layer 114 through the metal contact via (plug) 112B passing through the ILD 113, and is electrically connected to the DUT (the FET) 102 through the wire redistribution layer 114. The second RF pad 104 is used to output at least one first test signal TS1, received from the DUT (the FET) 102, to the detection controller (not shown) of the device-testing system 10 through the RF probe 12.

In the present embodiment, the first RF pad 103 may be a signal input pad, included in a group of ground-signal-ground (G-S-G) pads, responsible for receiving the first RF input signal RF-IN. The second RF pad 104 may be a signal output pad, included in the group of G-S-G pads, responsible for outputting a test signal (the first test signal TS1).

When performing a RF signal test on the DUT (the FET) 102, the three fingers 11A-11C of the RF probe 11 respectively contact the G-S-G pads of the first RF pad 103; the three fingers 12A-12C of the RF probe 12 respectively contact the G-S-G pads of the second RF pad 104. The RF probe 11, the RF probe 12, the first RF pad 103 and the second RF pad 104 are electrically connected to the DUT (the FET) 102 via the wire redistribution layer 114 to form a RF testing circuit RFC for detecting and analyzing the characteristics of the RF signal of the DUT (the FET) 102 during a RF operation.

In order to isolate the interference of the DC signal coming from the the RF probe 12, preferably, a DC signal isolation element 18, such as a T-type bias tee or a capacitor, can be optionally installed at the output end of the RF probe 12 to filter out the DC signal outputted from the RF probe 12.

The first DC pad 105 is yet another metal landing area disposed in the patterned metal layer 111. The first DC pad 105 can be electrically contacted with the wire redistribution layer 114 through a metal contact via 112C passing through the interlayer dielectric layer 113, and is electrically connected to the DUT (the FET) 102 through the wire redistribution layer 114. The first DC pad 105 is used to receive at least one DC input signal DC-IN output from the detection controller (not shown) of the device-testing system 10 through the DC probe 13, and to transmit the at least one DC input signal DC-IN to the DUT (the FET) 102. In order to isolate the interference of the RF signal input by the DC probe 13, a RF signal isolation element 17, such as an inductor, can be optionally installed at the input end of the DC probe 13.

The second DC pad 106 is yet another metal landing area disposed in the patterned metal layer 111. The second DC pad 106 can be electrically contacted with the wire redistribution layer 114 through a metal contact via 112D passing through the ILD 113, and electrically connected to the DUT (the FET) 102 through the wire redistribution layer 114. The second DC pad 106 is used to output at least one second test signal TS2 from the DUT (the FET) 102 and transmit it to the detection controller (not shown) of the device-testing system 10 through the DC probe 14.

When performing a DC signal test on the DUT (the FET) 102, the DC probe 14, the first DC pad 105 and the second DC pad 106 can be directly electrically connected to the DUT 102 through the wire redistribution layer 114, so as to form a DC testing loop CD1 for detecting and analyzing the DC signal of the DUT (the FET) 102. Since the reference layer of the DC test signal can be directly connected to the DUT 102, thus the DC signal no longer needs to pass through the first RF pad 103, the second RF pad 104 and any T-type bias tee. Such that, the voltage drop of the DC signal can be prevented and problems the DC signal instability can be improved.

The DC blocking element 107 is disposed on the semiconductor substrate (the semiconductor wafer) 101. In some embodiments of the present disclosure, the DC blocking element 107 may be a MOM capacitor, a MIM capacitor, or a resistor. One end of the DC blocking element 107 is connected to the first RF pad 103 through the wire redistribution layer 114; and the other end of the DC blocking element 107 is connected to the first DC pad 105 through the wire redistribution layer 114. When performing a RF signal test on the DUT 102, the first DC pad 105 can be used to block the DC signal interference coming from the first DC pad 105 from being input to the first RF pad 103.

In the present embodiment, the DC blocking element 107 is a MOM capacitor, which is composed of a plurality of stacked finger electrode patterns (e.g., the finger electrode patterns 107A-107D). In some embodiments of the present disclosure, the process for forming the DC blocking element 107 can be integrated with the process for forming the DUT (the FET) 102. In other words, the DUT (the FET) 102 and the DC blocking element 107 can be formed simultaneously. However, in other embodiments of the present disclosure, the process for forming the DC blocking element 107 and that for manufacturing the DUT (the FET) 102 can be alternatively independent form each other.

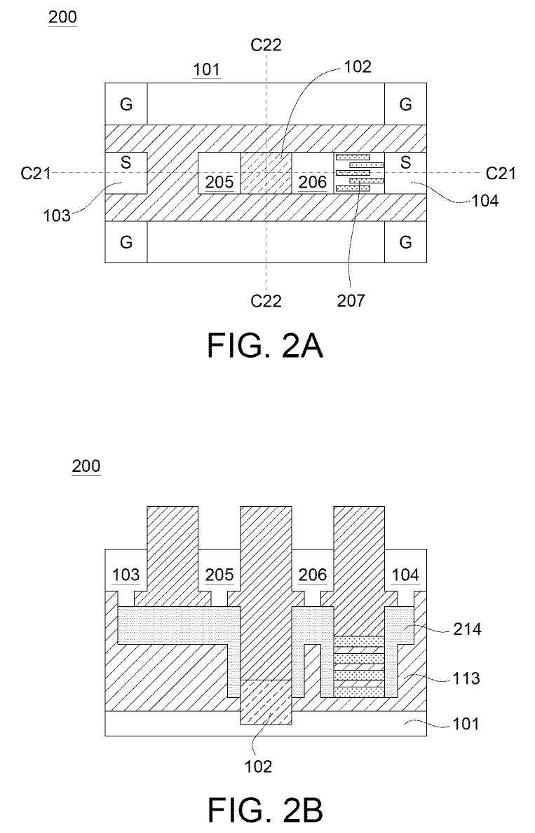

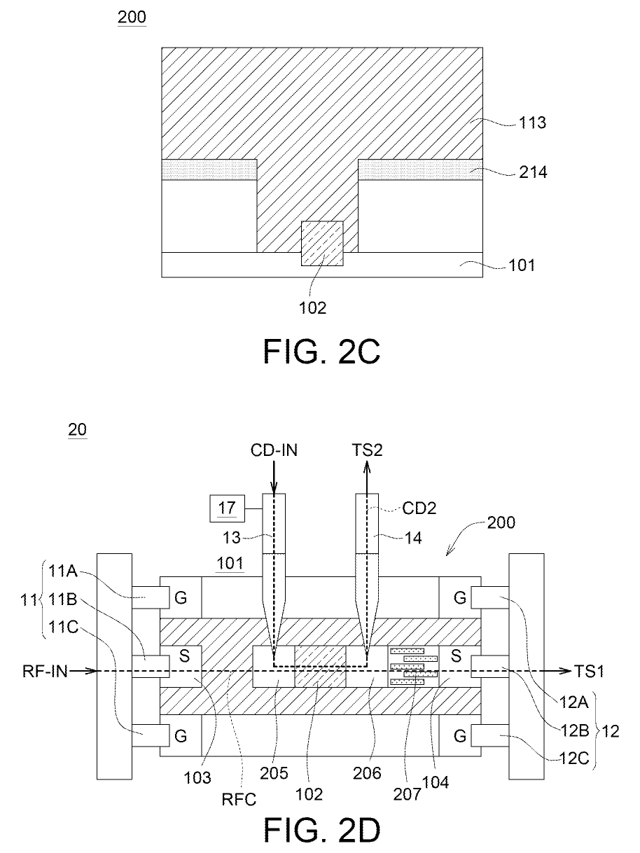

Referring to FIGS. 2A-2D, FIG. 2A is a top view illustrating another device-testing circuit structure 200 according to another embodiment of the present disclosure; FIG. 2B is a cross-sectional view of the device-testing circuit structure 200 taken along the cutting-line C21 as depicted in FIG. 2A; FIG. 2C is a cross-sectional view of the device-testing circuit structure 200 taken along the cutting-line C22 as depicted in FIGS. 2A; and 2D is a schematic diagram illustrating another device-testing system 20 applying the device-testing circuit structure 200 described in FIGS. 2A-2C.

The structure of the device-testing circuit structure 200 in the device-testing system 20 is similar to that of the device-testing circuit structure 100 in the device-testing system 10, and the difference there between is that the DC blocking element 207 has a different position in the device-testing circuit structure 200. In the present embodiment, one end of the DC blocking element 207 is connected to the second RF pad 104 through the wire redistribution layer 214; and the other end of the DC blocking element 207 is connected to the second DC pad 206 through the wire redistribution layer 214. When performing RF signal testing on the DUT 102, the DC blocking element 207 can be used to block DC signal interference coming from the first DC pad 205 and the second DC pad 206 from being input to the second RF pad 104. At the same time, the use of the DC signal isolation element 18 can be omitted.

When performing a DC signal test on the DUT 102, the first DC pad 205 and the second DC pad 206 can be directly electrically connected to the DUT 102 through the wire redistribution layer 114, so as to form a DC testing loop CD2. Since the reference layer of the DC test signal can be directly connected to the DUT 102, thus the DC test signal no longer needs to pass through the first RF pad 103, the second RF pad 104 and any T-type bias tee. Such that the voltage drop of the DC signal can be prevented and problems the DC signal instability can be improved. In addition, since the T-type bias tee can be completely omitted, the sizes of the device-testing circuit structure 200 and the device-testing system 20 can be miniaturized.

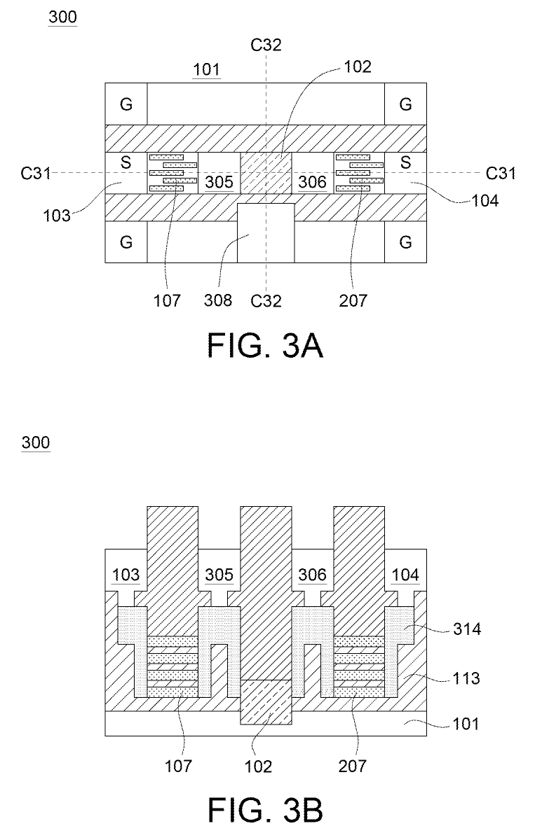

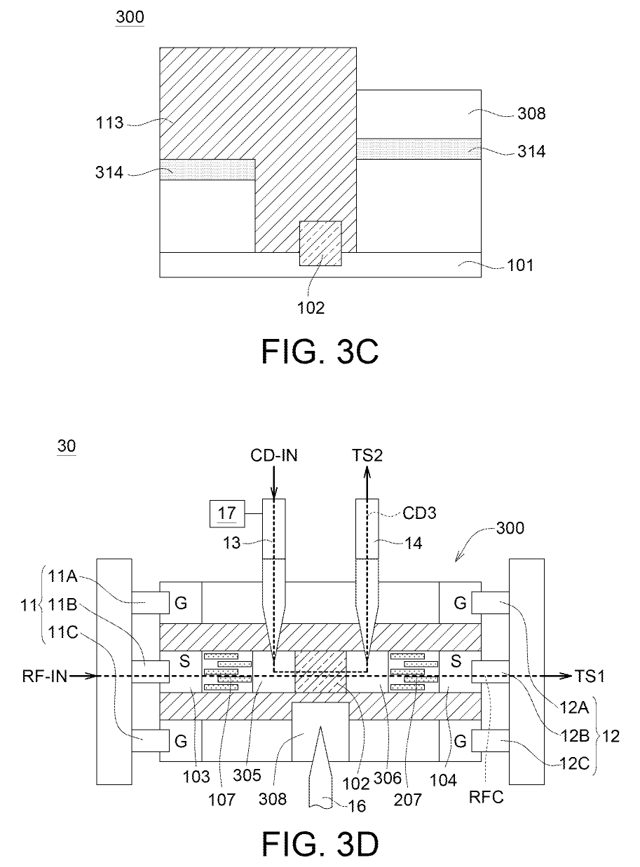

Referring to FIGS. 3A-3D, FIG. 3A is a top view illustrating yet another device-testing circuit structure 300 according to another embodiment of the present disclosure; FIG. 3B is a cross-sectional view of the device-testing circuit structure 300 taken along the cutting-line C31 as depicted in FIG. 3A; FIG. 3C is a cross-sectional view of the device-testing circuit structure 300 taken along the cutting-line C32 as depicted in FIGS. 3A; and 3D is a schematic diagram illustrating yet another device-testing system 30 applying the device-testing circuit structure 300 described in FIGS. 3A-3C.

The structure of the device-testing circuit structure 300 in the device-testing system 30 is similar to that of the device-testing circuit structure 100/200 in the device-testing system 10/20, and the difference there between is that the device-testing circuit structure 300 is configured with both DC blocking elements 107 and 207 and further includes a third DC pad 308 electrically connected to the DUT 102. The device-testing system 30 further includes another DC probe 16 electrically connected to the third DC pad 308.

When performing a RF signal test on the DUT 102, the DC blocking elements 107 and 207 can be used to block DC signal interference coming from the first DC pad 305 and the second DC pad 306 from being input to the second RF pad 104. When performing a DC signal test on the DUT 102, the first DC pad 305 and the second DC pad 306 can be directly electrically connected to the DUT 102 through the wire redistribution layer 314, so as to form a DC testing loop CD3. Since the reference layer of the DC test signal can be directly connected to the DUT 102, thus the DC signal no longer needs to pass through the first RF pad 103, the second RF pad 104 and any T-type bias tee. Such that, the voltage drop of the DC signal can be prevented and problems the DC signal instability can be improved. In addition, since the T-type bias tee can be completely omitted, the sizes of the device-testing circuit structure 300 and the device-testing system 30 can be miniaturized.

In accordance with the aforementioned embodiments of the present disclosure, a device-testing circuit structure 100/200/300 and a device-testing system 10/20/30 applying the same are provided, which includes a RF testing circuit disposed on a semiconductor substrate (e.g., a semiconductor wafer or a semiconductor chip/die) 101 for testing a DUT 102. The RF testing circuit includes a first RF pad 103 for receiving an RF input signal RF-IN and transmit it into the DUT 102, and a second RF pad 104 for outputting a test signal TS1 from the DUT 102. At least one DC pad 105/205/305 or/and 106/206/306 is added to the connection line between the first RF pad 103 and the DUT 102 or/and between the second RF pad 104 and the DUT 102, so that one end of the DC pad 105/205/305 or/and 106/206/306 is directly electrically connected to the DUT102, forming a DC testing loop CD1/CD2/CD3 with the DUT 102. Thereby, the reference layer of the DC testing loop can be directly connected to the DUT 102 without passing through the first RF pad 103 or the second RF pad 104, which helps to improve the problem of signal instability caused by voltage drop of the DC signal (e.g. the second test signal TS2).

In addition, at least one DC blocking element (e.g., MOM capacitor, MIM capacitor or resistor) 107 or 207 is added between the first DC pad 105/205/305 and the corresponding first RF pad 103 and/or between the second DC pad 106/206/306 and the corresponding second RF pad 104 to block the interference of the DC signal coming from the DC pad 105/205/305 or/and 106/206/306 bothering the RF test circuit. As a result, the device-testing circuit structure 100/200/300 and device-testing system 10/20/30 can detect the RF and DC signal characteristics of the DUT respectively, without additionally setting bias tee on the probe, as the prior art does. These designs can not only improve the stability of the DC signal, but also further simplify the structures of the device-testing circuit structure 100/200/300 and the device-testing system 10/20/30.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A device-testing circuit structure used to test a device under test (DUT) disposed on a semiconductor substrate, comprising:
a first RF pad, disposed on the semiconductor substrate, and used to receive at least one RF input signal and transit it to the DUT;
a second RF pad, disposed on the semiconductor substrate, electrically connected to the DUT, and used to output at least one first test signal from the DUT;
a first DC pad, disposed on the semiconductor substrate and used to receive at least one DC input signal and transit it to the DUT;
a second DC pad and, disposed on the semiconductor substrate and used to output at least one second test signal from the DUT; and
a first DC blocking element, disposed on the semiconductor substrate;
wherein one end of the first DC blocking element is connected to one of the first DC pad and the second DC pad; another end of the first DC blocking element is correspondingly connected to one of the first RF pad and the second RF pad.

2. The device-testing circuit structure according to claim 1, further comprising a second DC blocking element, disposed on the semiconductor substrate; wherein one end of the second DC blocking element is connected to another one of the first DC pad and the second DC pad; another end of the second DC blocking element is correspondingly connected to another one of the first RF pad and the second RF pad.

3. The device-testing circuit structure according to claim 1, further comprising a third DC pad electrically connected to the DUT.

4. The device-testing circuit structure according to claim 1, wherein the first RF pad is included in a first group of ground-signal-ground (G-S-G) pads and electrically connected to the DUT; the second RF pad is included in a second group of G-S-G pads and electrically connected to the DUT.

5. The device-testing circuit structure according to claim 1, wherein the first DC blocking element is a metal-oxide-metal (MOM) capacitor, a metal-insulator-metal (MIM) capacitor or a resistor.

6. A device-testing system used to test a DUT disposed on a semiconductor substrate, comprising:
a first RF pad, disposed on the semiconductor substrate, and used to receive at least one RF input signal and transit it to the DUT;
a second RF pad, disposed on the semiconductor substrate, electrically connected to the DUT, and used to output at least one first test signal from the DUT;
a first DC pad, disposed on the semiconductor substrate and used to receive at least one DC input signal and transit it to the DUT;
a second DC pad and, disposed on the semiconductor substrate and used to output at least one second test signal from the DUT;
a first DC blocking element, disposed on the semiconductor substrate; wherein one end of the first DC blocking element is connected to one of the first DC pad and the second DC pad; another end of the first DC blocking element is correspondingly connected to one of the first RF pad and the second RF pad.
a first probe, used to contact the first RF pad and output the at least one RF input signal;
a second probe, contacting the second RF pad and used to form an RF signal testing loop with the DUT, the first RF pad and the first probe to output the at least one first test signal;
a third probe, contacting the first DC pad and used to output the at least one DC input signal; and
a fourth probe contacting the second DC pad and used to form a DC signal testing loop with the DUT, the first DC pad and the third probe to output the at least one second test signal.

7. The device-testing system according to claim 6, further comprising a second DC blocking element, disposed on the semiconductor substrate; wherein one end of the second DC blocking element is connected to another one of the first DC pad and the second DC pad; another end of the second DC blocking element is correspondingly connected to another one of the first RF pad and the second RF pad.

8. The device-testing system according to claim 6, further comprising a third DC pad electrically connected to the DUT.

9. The device-testing system according to claim 6, wherein the first RF pad is included in a first group of ground-signal-ground (G-S-G) pads and electrically connected to the DUT; the second RF pad is included in a second group of G-S-G pads and electrically connected to the DUT.

10. The device-testing system according to claim 6, wherein the first DC blocking element is a MOM capacitor, a MIM capacitor or a resistor.

11. The device-testing system according to claim 6, further comprising an inductor electrically connected to the third probe.
